(19) United States
(12) Patent Application Publication
(10) Pub. No.: US 2026/0013379 A1
(43) Pub. Date: Jan. 8, 2026

(54) DISPLAY DEVICE AND ELECTRONIC DEVICE

(71) Applicant: Samsung Display Co., LTD., Yongin-si (KR)

(72) Inventors: Jae Hun LEE, Yongin-si (KR); Jun Gi KIM, Yongin-si (KR); Youn Joo RYU, Yongin-si (KR); Sang Hyun YUN, Yongin-si (KR); Hyun Young JUNG, Yongin-si (KR); Gwang Min CHA, Yongin-si (KR)

(73) Assignee: Samsung Display Co., LTD., Yongin-si (KR)

(21) Appl. No.: 19/081,498

(22) Filed: Mar. 17, 2025

(30) Foreign Application Priority Data
Jul. 2, 2024 (KR) 10-2024-0086974

(51) Int. Cl. H10K 59/80

(52) U.S. Cl. CPC H10K 59/879

(57) ABSTRACT

Provided are a display device and an electronic device. A display device includes, a substrate, a light-emitting element layer disposed on the substrate, and including a plurality of light-emitting elements, and a light control layer disposed on the light-emitting element layer, wherein the light control layer includes, a light-transmitting film, an opening penetrating at least a part of the light-transmitting film, a core layer disposed in the opening, a clad layer disposed on the core layer, and a light-blocking film disposed on the clad layer, wherein a refractive index of the core layer is greater than a refractive index of the light-transmitting film and a refractive index of the clad layer.

### CROSS-REFERENCE TO RELATED APPLICATION

This application claims priority to and benefits of Korean Patent Application No. 10-2024-0086974 under 35 U.S.C. § 119, filed on Jul. 2, 2024, in the Korean Intellectual Property Office, the entire contents of which are incorporated herein by reference.

### BACKGROUND

### 1. Technical Field

Embodiments relate to a display device and an electronic device.

### 2. Description of the Related Art

With the advance of information-oriented society, more and more demands are placed on display devices for displaying images in various ways. The display device may be a display device such as a liquid crystal display, a field emission display and a light-emitting display. The light-emitting display may include an organic light-emitting display device including an organic light-emitting diode as a light-emitting element or an inorganic light-emitting display device including an inorganic light-emitting diode as a light-emitting element.

In the case of a vehicle display device, in case that the image displayed on the vehicle display device disposed in front of the driver or passenger is reflected on the windshield at night, it may interfere with the driver's driving, so that it is necessary to control the viewing angle of the image displayed on the vehicle display device. It is necessary to control the viewing angle of the image displayed on the vehicle display device such that the image displayed on the vehicle display device disposed in front of the driver is not provided to the passenger to protect privacy.

### SUMMARY

Aspects of the disclosure provide a display device and an electronic device with increased light efficiency.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an aspect of the disclosure, there is provided a display device including, a substrate, a light-emitting element layer disposed on the substrate, and including a plurality of light-emitting elements, and a light control layer disposed on the light-emitting element layer, wherein the light control layer includes, a light-transmitting film, an opening penetrating at least a part of the light-transmitting film, a core layer disposed in the opening, a clad layer disposed on the core layer, and a light-blocking film disposed on the clad layer, wherein a refractive index of the core layer may be greater than a refractive index of the light-transmitting film and a refractive index of the clad layer.

In an embodiment, the core layer may cover an inner sidewall of the opening.

In an embodiment, the clad layer may cover an inner sidewall of the core layer.

In an embodiment, the light-blocking film may be disposed in a groove formed by an inner sidewall of the clad layer.

In an embodiment, a difference between the refractive index of the core layer and the refractive index of the clad layer may be in a range of about 0.05 to about 0.2.

In an embodiment, the refractive index of the core layer may be in a range of about 1.45 to about 1.8.

In an embodiment, the refractive index of the clad layer may be in a range of about 1.4 to about 1.6.

In an embodiment, the light control layer may further include a light-transmitting lower film disposed between the light-emitting element layer and the light-transmitting film, and the opening may penetrate an upper surface of the light-transmitting lower film.

In an embodiment, a difference between the refractive index of the core layer and a refractive index of the light-transmitting lower film may be in a range of about 0.05 to about 0.2.

In an embodiment, a refractive index of the light-transmitting lower film may be in a range of about 1.4 to about 1.6.

In an embodiment, a bottom portion of the opening may have a flat surface.

In an embodiment, a bottom portion of the opening may be convex toward the light-emitting element layer.

In an embodiment, the bottom portion of the opening may have an inclined surface.

In an embodiment, the bottom portion of the opening may have a curved surface.

According to an aspect of the disclosure, there is provided a display device including, a substrate, a light-emitting element layer disposed on the substrate, and including a plurality of light-emitting elements, and a light control layer disposed on the light-emitting element layer, wherein the light control layer includes, a light-transmitting film, an opening penetrating at least a part of the light-transmitting film, a core layer disposed on the light-transmitting film, and a light-blocking film disposed on the core layer, wherein a refractive index of the core layer may be greater than a refractive index of the light-transmitting film and a refractive index of the light-blocking film.

In an embodiment, the core layer may be disposed on an inner sidewall of the opening and an upper surface of the light-transmitting film.

In an embodiment, the core layer may have a conformal shape along the inner sidewall of the opening and the upper surface of the light-transmitting film.

In an embodiment, a difference between the refractive index of the core layer and the refractive index of the light-blocking film may be in a range of about 0.05 to about 0.2.

In an embodiment, the light control layer may further include a light-transmitting lower film disposed between the light-emitting element layer and the light-transmitting film, and the opening penetrates an upper surface of the light-transmitting lower film.

According to an aspect of the disclosure, there is provided an electronic device includes a display device, the display device including, a substrate, a light-emitting element layer disposed on the substrate, and including a plurality of light-emitting elements, and a light control layer disposed on the light-emitting element layer, wherein the light control layer includes, a light-transmitting film, an opening penetrating at least a part of the light-transmitting film, a core layer disposed in the opening, a clad layer disposed on the core layer, and a light-blocking film disposed on the clad layer, wherein a refractive index of the core layer may be greater than a refractive index of the light-transmitting film and a refractive index of the clad layer.

According to the display device and an electronic device according to an embodiment, light efficiency can be increased.

However, effects according to the embodiments are not limited to those examples above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view showing a display device according to an embodiment;

FIG. 2 is a schematic plan view illustrating a display device according to an embodiment;

FIG. 3 is a schematic cross-sectional view of the display device taken along line X1-X1′ of FIG. 2;

FIG. 4 is a schematic diagram in case that a display device according to an embodiment is applied to a vehicle;

FIG. 5 is a schematic cross-sectional view illustrating an example of a display panel according to an embodiment;

FIG. 6 is a schematic cross-sectional view illustrating a portion of a display device according to an embodiment;

FIG. 7 is a schematic cross-sectional view taken along line X2-X2′ of FIG. 6;

FIG. 8 is a schematic diagram showing a path of light traveling along a core layer according to an embodiment;

FIG. 9 is a schematic cross-sectional view showing a display panel according to another embodiment;

FIGS. 10 and 11 are schematic cross-sectional views of a display panel according to still another embodiment;

FIG. 12 is a schematic diagram showing a path of light traveling along a core layer according to still another embodiment;

FIG. 13 is an enlarged schematic view of area A of FIG. 12;

FIG. 14 is a schematic diagram showing a light path in a display panel according to a comparative example;

FIG. 15 is a schematic diagram showing a light path in the display panel according to the embodiment of FIG. 11; and

FIGS. 16 and 17 are schematic perspective views illustrating application examples of electronic devices.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Hereinafter, embodiments will be described in detail with reference to the accompanying drawings.

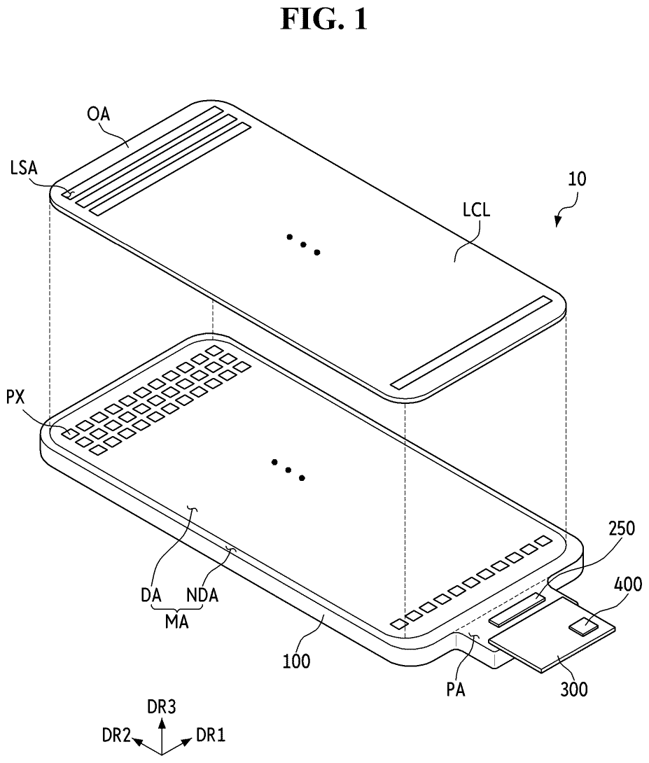

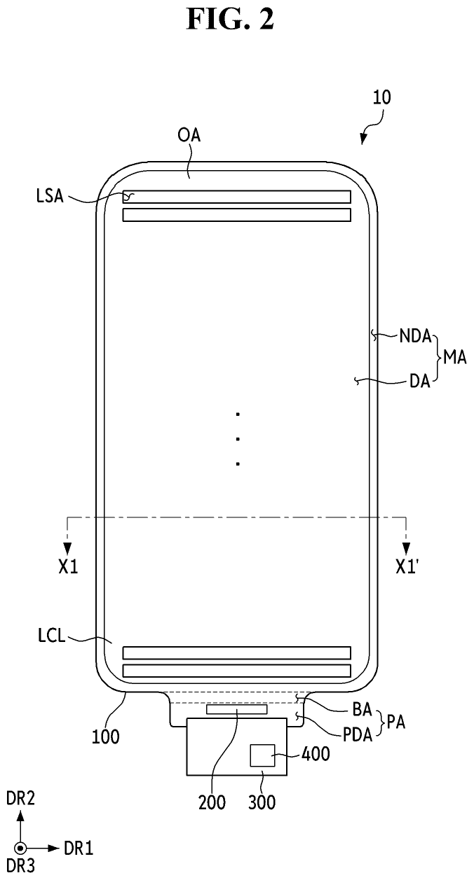

FIG. 1 is a schematic perspective view showing a display device according to an embodiment. FIG. 2 is a schematic plan view illustrating a display device according to an embodiment.

Referring to FIGS. 1 and 2, a display device 10, which is a device for displaying a moving image or a still image, may be used as a display screen of various devices, such as an automobile, a television, a laptop computer, a monitor, a billboard and an Internet-of-Things (IoT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

In some embodiments, in case that the display device 10 is used as a display screen of a vehicle, the display device 10 may be a vehicle display. The vehicle display may provide users with not only information about vehicle's operation and status, but also various services such as convenience functions and media content. In case that the display device 10 includes an input unit such as a touch panel, the user may operate various functions such as driving modes of the vehicle and convenience functions through the display device 10.

The display device 10 may be any one of an organic light-emitting display device, a liquid crystal display device, a plasma display device, a field emission display device, an electrophoretic display device, an electrowetting display device, a quantum dot light-emitting display device, a micro LED display device, and the like. In the following description, it is assumed that the display device 10 is an organic light-emitting display device, but embodiments are not limited thereto.

The display device 10 according to an embodiment may include a display panel 100, a display driving circuit 250, a circuit board 300, and a touch driving circuit 400.

The display panel 100 may include pixels PX arranged in a first direction DR1 and a second direction DR2. Each of the pixels PX may have a rectangular shape, a square shape, or a rhombic shape in plan view. For example, as shown in the drawing, each of the pixels PX may have a square shape in plan view. However, embodiments are not limited thereto, and may have various shapes such as a polygon, a circle, and an ellipse in plan view.

In the illustrated figure, the first direction DR1 and the second direction DR2 intersect each other as horizontal directions. For example, the first direction DR1 and the second direction DR2 may be orthogonal to each other. A third direction DR3 crosses the first direction DR1 and the second direction DR2, and may be, for example, perpendicular directions orthogonal to each other. In the disclosure, a direction indicated by each of the first to third directions DR1, DR2, and DR3 on the drawings may be referred to as a side, and an opposite direction thereto may be referred to as the other side. Unless otherwise specified, each direction may include both sides. Unless otherwise defined, in the description, directions indicated by arrows of the first to third directions DR1, DR2, and DR3 may be referred to as a side, and the opposite directions thereto may be referred to as the other side. Also, the terms “above,” “upper side,” “upper portion,” “top,” and “top surface,” as used herein, refer to a direction indicated by an arrow in the drawing in the third direction DR3 based on the drawings, and the terms “below,” “lower side,” “lower portion,” “bottom,” and “bottom surface,” as used herein, refer to a direction opposite to the direction indicated by the arrow in the third direction DR3 based on the drawings.

The display panel 100 may include a main region MA and a protrusion area PA protruding from a side of the main region MA.

The main region MA may, in plan view, be formed in a rectangular shape having short sides in a first direction DR1 and long sides in a second direction DR2 intersecting the first direction DR1. The corner where the short side in the first direction DR1 and the long side in the second direction DR2 meet may be rounded to have a selected curvature or may be right-angled. The planar shape of the display device 10 is not limited to a quadrilateral shape, and may be formed in another polygonal shape, a circular shape, or an elliptical shape. The main region MA may be formed flat, but embodiments are not limited thereto, and may include curved portions formed at left and right ends. For example, the curved portions may have a constant curvature or a changing curvature.

The main region MA may include a display area DA where pixels are formed to display an image and a non-display area NDA which is a peripheral area of the display area DA.

In the display area DA, not only the pixels, but also scan lines, data lines, and power lines connected to the pixels may be disposed. In case that the main region MA includes a curved portion, the display area DA may be disposed on the curved portion. For example, the image of the display panel 100 may also be seen on the curved portion.

The non-display area NDA may be defined as an area from the boundary of the display area DA to the edge portion of the display panel 100. A scan driver for applying scan signals to the scan lines and link lines connecting the data lines to the display driving circuit 250 may be disposed in the non-display area NDA.

The protrusion area PA may protrude from a side of the main region MA. For example, the protrusion area PA may protrude from the lower side of the main region MA as shown in FIG. 2. A length of the protrusion area PA in the first direction DR1 may be less than a length of the main region MA in the first direction DR1.

The protrusion area PA may include a bending area BA and a pad area PDA. For example, the pad area PDA may be disposed on the side of the bending area BA, and the main region MA may be disposed on another side of the bending area BA. For example, the pad area PDA may be disposed below the bending area BA, and the main region MA may be disposed above the bending area BA.

The display panel 100 may be formed flexibly such that it can be curved, bent, folded, or rolled. Accordingly, the display panel 100 may be bent in the thickness direction, e.g., in the third direction DR3 in the bending area BA. For example, a surface of the pad area PDA of the display panel 100 may face upward before the display panel 100 is bent, but after the display panel 100 is bent, the surface of the pad area PDA of the display panel 100 may face downward. Accordingly, since the pad area PDA is disposed below the main region MA, the pad area PDA may overlap the main region MA.

Pads electrically connected to the display driving circuit 250 and the circuit board 300 may be disposed in the pad area PDA of the display panel 100.

The display driving circuit 250 may output signals and voltages for driving the display panel 100. For example, the display driving circuit 250 may supply data voltages to data lines. Further, the display driving circuit 250 may supply a power voltage to the power line, and may supply scan control signals to the scan driver. The display driving circuit 250 may be formed as an integrated circuit (IC) and mounted on the display panel 100 in the pad area PDA by a chip on glass (COG) method, a chip on plastic (COP) method, or an ultrasonic bonding method, but embodiments are not limited thereto. For example, the display driving circuit 250 may be mounted on the circuit board 300.

The pads may include display pads electrically connected to the display driving circuit 250 and touch pads electrically connected to touch lines.

The circuit board 300 may be attached onto the pads using an anisotropic conductive film. Accordingly, lead lines of the circuit board 300 may be electrically connected to the pads. The circuit board 300 may be a flexible printed circuit board, a printed circuit board, or a flexible film such as a chip on film.

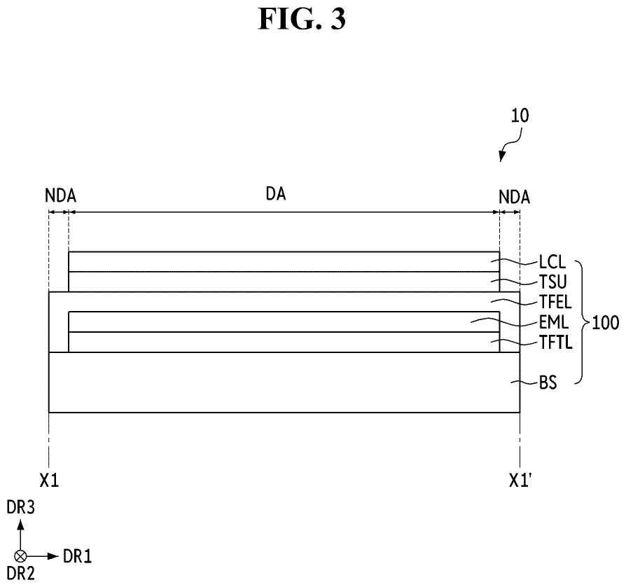

The touch driving circuit 400 may be connected to touch electrodes of a touch sensor layer TSU (see FIG. 3) of the display panel 100. The touch driving circuit 400 may apply driving signals to the touch electrodes of the touch sensor layer TSU (see FIG. 3) and may measure capacitance values of the touch electrodes. The driving signal may be a signal having driving pulses. The touch driving circuit 400 may determine whether or not touch is inputted based on the capacitance values, and may calculate touch coordinates at which touch is inputted.

The touch driving circuit 400 may be disposed on the circuit board 300. The touch driving circuit 400 may be formed as an integrated circuit (IC) and mounted on the circuit board 300.

In the display device 10 according to the embodiment, the display panel 100 may further include a light control layer LCL.

The light control layer LCL may be disposed (e.g., directly disposed) on the main region MA of the display panel 100. For example, the light control layer LCL may be embedded in the display panel 100 and disposed (e.g., directly disposed) on the main region MA of the display panel 100. By embedding the light control layer LCL in the display panel 100, the thickness and manufacturing cost of the display device 10 may be reduced compared to a case where a separate light control film is attached.

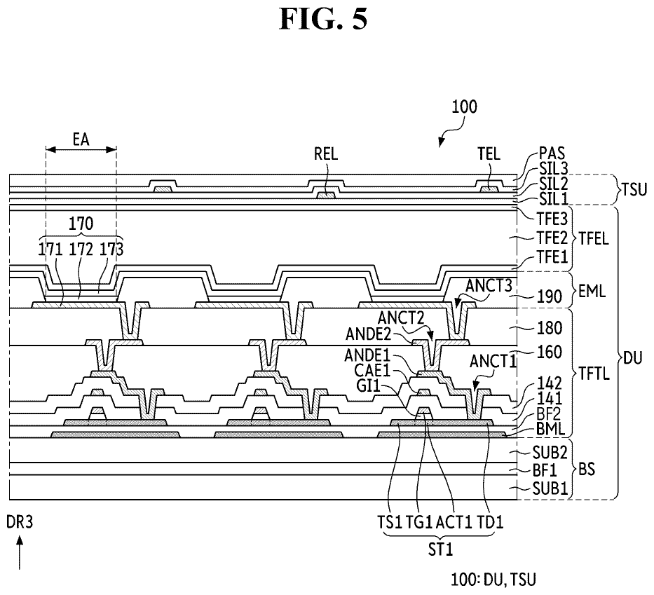

In some embodiments, the light control layer LCL may be disposed on the display area DA of the main region MA. The light control layer LCL may adjust the viewing angle of light emitted from a light-emitting layer 172 (see FIG. 5) of the display panel 100.

However, embodiments are not limited thereto, and the size of the light control layer LCL may be larger than that of the display area DA in plan view. For example, the light control layer LCL may overlap both the display area DA and the non-display area NDA.

In some embodiments, the light control layer LCL may include a transmission area OA and a non-transmission area LSA.

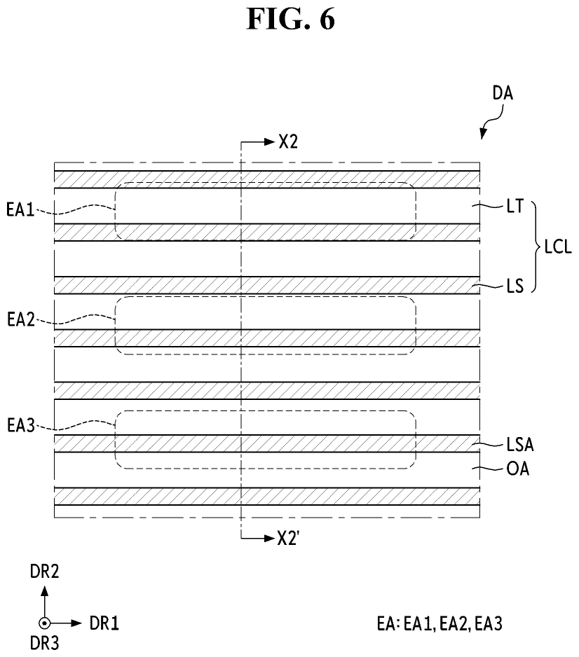

The transmission area OA may be an area where a light-blocking film LS (see FIG. 6) may not be disposed. The transmission area OA may be an area that transmits light and may extend along the third direction DR3.

The transmission area OA may have a quadrilateral shape in plan view, as illustrated in FIGS. 1 and 2, but embodiments are not limited thereto. The transmission area OA may have a circular shape, an elliptical shape, or a polygonal shape in plan view. In some embodiments, the shape of the transmission area OA may substantially correspond to the shape of the display panel 100.

The non-transmission areas LSA may be the remaining areas of the light control layer LCL excluding the transmission areas OA. The non-transmission areas LSA may be areas in which the light-blocking film LS (see FIG. 6) is disposed.

In some embodiments, the non-transmission areas LSA may extend in the first direction DR1 or the second direction DR2. For example, as shown in FIG. 1, the non-transmission areas LSA may extend in the first direction DR1 and may be arranged along the second direction DR2. As another example, the non-transmission areas LSA may extend in the second direction DR2 and may be arranged along the first direction DR1. As still another example, some of the non-transmission areas LSA may extend in the first direction DR1 and may be arranged along the second direction DR2, while the remainder of the non-transmission areas LSA may extend in the second direction DR2 and may be arranged along the first direction DR1.

In an embodiment, as shown in FIG. 1, in case that the non-transmission areas LSA are arranged along the second direction DR2, the viewing angle may be controlled in the second direction DR2. In another embodiment, in case that the non-transmission areas LSA are arranged along the first direction DR1, the viewing angle may be controlled in the first direction DR1. In the display device 10 according to an embodiment, the arrangement and shape of the transmission areas OA and the non-transmission areas LSA may be changed in various ways according to the required control direction of the viewing angle.

For example, the drawing illustrates that the transmission area OA is disposed to surround the non-transmission areas LSA, but embodiments are not limited thereto. In some embodiments, the transmission area OA may include transmission areas OA, and the plurality of transmission areas OA may extend in the same direction as the non-transmission areas LSA, so that the transmission areas OA and the non-transmission areas LSA may be arranged alternately with each other. For example, as shown in FIG. 1, in case that the non-transmission areas LSA extend in the first direction DR1, the plurality of transmission areas OA may extend in the first direction DR1 and may be arranged alternately with the non-transmission areas LSA in the second direction DR2.

The light control layer LCL may include the light-blocking film LS (see FIG. 6) that blocks light emitted from the light-emitting layer 172 (see FIG. 5) of the display panel 100, and a light-transmitting film LT (see FIG. 6) that transmits the light. A detailed structure of the light control layer LCL will be described later with reference to FIG. 6 and the like.

FIG. 3 is a schematic cross-sectional view of the display device taken along line X1-X1′ of FIG. 2.

Referring to FIG. 3, the display device 10 may include the display panel 100 in which the light control layer LCL is embedded. The display panel 100 may include a base member BS, a thin-film transistor layer TFTL, a light-emitting element layer EML, a thin-film encapsulation layer TFEL, the touch sensor layer TSU, and the light control layer LCL.

The base member BS may include a substrate. The substrate may be formed of an insulating material such as glass, quartz, or a polymer resin. Examples of a polymer material may include polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (TAC), cellulose acetate propionate (CAP), or a combination thereof. In another example, the substrate may include a metal material.

The substrate may be a rigid substrate or a flexible substrate which can be bent, folded or rolled. In case that the substrate is a flexible substrate, the substrate may be formed of polyimide (PI), but embodiments are not limited thereto.

The thin-film transistor layer TFTL may be disposed on the base member BS. In the thin-film transistor layer TFTL, scan lines, data lines, power lines, scan control lines, and link lines connecting pads to data lines, as well as thin-film transistors of each of the pixels, may be formed. Each of the thin-film transistors may include a gate electrode, a semiconductor layer, a source electrode, and a drain electrode.

The thin-film transistor layer TFTL may be disposed in the display area DA and the non-display area NDA. For example, thin-film transistors, scan lines, data lines, and power lines of each of the pixels of the thin-film transistor layer TFTL may be disposed in the display area DA. The scan control lines and the link lines of the thin-film transistor layer TFTL may be disposed in the non-display area NDA.

A light-emitting element layer EML may be disposed on the thin-film transistor layer TFTL. The light-emitting element layer EML may include pixels including a first electrode, a light-emitting layer, and a second electrode, and a pixel defining layer defining the pixels. The light-emitting layer may be an organic light-emitting layer containing an organic material. For example, the light-emitting layer may include a hole transporting layer, an organic light-emitting layer, and an electron transporting layer. In case that the first electrode is applied with a selected voltage through the thin-film transistor of the thin-film transistor layer TFTL and the second electrode is applied with a cathode voltage, holes and electrons may be transferred to the organic light-emitting layer through a hole transporting layer and an electron transporting layer, respectively and may be combined with each other to emit light in the organic light-emitting layer. The pixels of the light-emitting element layer EML may be disposed in the display area DA.

The thin-film encapsulation layer TFEL may be disposed on the light-emitting element layer EML. The thin-film encapsulation layer TFEL may prevent oxygen or moisture from permeating into the light-emitting element layer EML. For example, the thin-film encapsulation layer TFEL may include at least one inorganic film. The inorganic film may be a silicon nitride layer, a silicon oxynitride layer, a silicon oxide layer, a titanium oxide layer, or an aluminum oxide layer, but embodiments are not limited thereto. For example, the thin-film encapsulation layer TFEL may protect the light-emitting element layer EML from foreign substances such as dust. For example, the thin-film encapsulation layer TFEL may include at least one organic film. The organic film may include acryl resin, epoxy resin, phenolic resin, polyamide resin, or polyimide resin, but embodiments are not limited thereto.

The thin-film encapsulation layer TFEL may be disposed in both the display area DA and the non-display area NDA. For example, the thin-film encapsulation layer TFEL may cover the light-emitting element layer EML in the display area DA and the non-display area NDA, and may cover the thin-film transistor layer TFTL in the non-display area NDA.

The touch sensor layer TSU may be disposed on the thin-film encapsulation layer TFEL. Since the touch sensor layer TSU is directly disposed on the thin-film encapsulation layer TFEL, it has the advantage of reducing the thickness of the display device 10 compared to a case where a separate touch panel including the touch sensor layer TSU is attached on the thin-film encapsulation layer TFEL.

The touch sensor layer TSU may include touch electrodes for sensing a user's touch in a capacitive manner and the touch lines connecting the pads to the touch electrodes. For example, the touch sensor layer TSU may sense a user's touch using a self-capacitance method or a mutual capacitance method.

The touch electrodes of the touch sensor layer TSU may be disposed in a touch sensor area overlapping the display area DA. The touch lines of the touch sensor layer TSU may be disposed in a touch peripheral area overlapping the non-display area NDA.

The light control layer LCL may be disposed on the touch sensor layer TSU. The light control layer LCL may overlap the display area DA. The light control layer LCL may absorb or block light that travels out of a certain angle with respect to the third direction DR3 among light emitted from the light-emitting element layer EML. For example, the light control layer LCL may control the viewing angle.

For example, the display device 10 may further include a cover window. The cover window may be additionally disposed on the light control layer LCL, and the light control layer LCL and the cover window may be attached by a transparent adhesive member such as an optically clear adhesive (OCA) film.

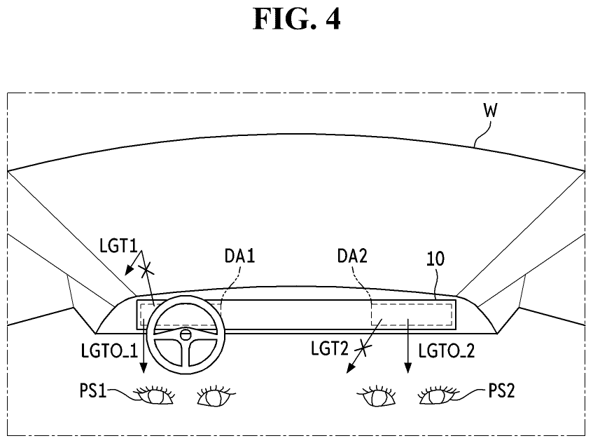

FIG. 4 is a schematic diagram in case that a display device according to an embodiment is applied to a vehicle.

Referring to FIG. 4, the display device 10 according to an embodiment may be, for example, the display device applied to the vehicle. The vehicle may include a body forming an exterior of the vehicle and an interior space defined by the body. The body may include a windshield W that protects the driver PS1 and the passenger PS2 from the outside and provides a view to the driver PS1. As illustrated in the drawing, the display device 10 may be provided in the interior space.

In some embodiments, the display device 10 may be disposed on a dashboard provided in the interior space. For example, as shown in FIG. 4, the display device 10 may extend from the dashboard positioned in front of the driver's seat to the dashboard positioned in front of the passenger's seat. For example, the display device 10 may be an integral display continued from the dashboard positioned in front of the driver's seat to the dashboard positioned in front of the passenger's seat.

For example, the display device 10 may include a first display area DA1 positioned in front of the driver's seat and a second display area DA2 positioned in front of the passenger's seat. The first display area DA1 may be disposed on the dashboard in front of the driver's seat to provide speed information and the like to the driver PS1. The second display area DA2 may be disposed on the dashboard in front of the passenger's seat to provide entertainment content and the like to the passenger PS2. For example, a third display area may be further included between the first display area DA1 and the second display area DA2.

As another example, the display devices 10 may be disposed on the dashboard in front of the driver's seat and the dashboard in front of the passenger's seat, respectively. For example, a first display device may be disposed on the dashboard in front of the driver's seat, and a second display device may be disposed on the dashboard in front of the passenger's seat.

The driver PS1 may visually recognize the display screen of the display device 10 through light LGTO_1 emitted from the display device 10 in front of the driver's seat toward the driver PS1. However, light LGT1, which is some of the light emitted from the display device 10 in front of the driver's seat, may be reflected on the surrounding windshield W and provided to the driver PS1. For example, the image reflected on the windshield W may interfere with driving of the driver PS1′. On the other hand, in the case of the display device 10 according to an embodiment, by adjusting the viewing angle of the lights emitted from the display device 10 in a front direction (e.g., direction facing the driver PS1), particularly, the vertical viewing angle, the light LGT1 that is some of the light emitted from the display device 10 in front of the driver's seat may be prevented from being reflected on the surrounding windshield W and provided to the driver PS1.

The passenger PS2 may visually recognize the display screen of the display device 10 through light LGTO_2 emitted from the display device 10 in front of the passenger's seat toward the passenger PS2. However, light LGT2, which is some of the light emitted from the display device 10 in front of the passenger's seat, may be provided toward the driver PS1. For example, the driver PS1 may be restricted from viewing when the vehicle is in motion for safety reasons. In the case of the display device 10 according to an embodiment, by adjusting the viewing angle of the lights emitted from the display device 10 in the frontal direction (e.g., the direction facing the passenger PS2), e.g., the horizontal viewing angle, the light LGT2 that is some of the light emitted from the display device 10 in front of the passenger's seat may be prevented from being provided to the driver.

The drawing illustrates that the display device 10 in front of the driver's seat adjusts the vertical viewing angle, and the display device 10 in front of the passenger's seat adjusts the horizontal viewing angle, but embodiments are not limited thereto. For example, the display device 10 in front of the driver's seat may adjust the horizontal viewing angle, and the display device 10 in front of the passenger's seat may adjust the vertical viewing angle. As another example, the display device 10 in front of the driver's seat and the display device 10 in front of the passenger's seat may adjust both the vertical viewing angle and the horizontal viewing angle.

The viewing angles may be adjusted through the light control layer LCL. The viewing angles may be limited to a selected angle range through the light control layer LCL. For example, in case that an imaginary line that faces the driver PS1 or the passenger PS2 and extends in a direction perpendicular to the display surface of the display device 10 is taken as a normal line, the viewing angle may be within about 35° from the normal line. In some embodiments, the angle within about 35° from the normal line may be defined as an effective viewing angle, but embodiments are not limited thereto.

FIG. 5 is a schematic cross-sectional view illustrating an example of a display panel according to an embodiment.

Referring to FIG. 5, the display panel 100 may include a display layer DU and the touch sensor layer TSU. The display layer DU may include the base member BS, the thin-film transistor layer TFTL, the light-emitting element layer EML, and the thin-film encapsulation layer TFEL.

The base member BS may include a first substrate SUB1, a first buffer film BF1 disposed on the first substrate SUB1, and a second substrate SUB2 disposed on the first buffer film BF1.

The first substrate SUB1 and the second substrate SUB2 may be made of an insulating material such as glass, quartz, polymer resin or the like. Examples of a polymer material may include polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (TAC), cellulose acetate propionate (CAP), or a combination thereof. In another example, the substrate may include a metal material.

The first substrate SUB1 and the second substrate SUB2 may be a rigid substrate, or a flexible substrate which can be bent, folded or rolled. In case that the substrate is a flexible substrate, the substrate may be formed of polyimide (PI), but embodiments are not limited thereto.

The first buffer film BF1 may be a film for protecting a first thin-film transistor ST1 and the light-emitting layer 172 from moisture permeating through the first substrate SUB1 and the second substrate SUB2 which are susceptible to moisture permeation. The first buffer film BF1 may be formed of inorganic films that are alternately stacked. For example, the first buffer film BF1 may be formed of multiple films in which one or more inorganic films of a silicon nitride layer, a silicon oxynitride layer, a silicon oxide layer, a titanium oxide layer and an aluminum oxide layer are alternately stacked.

The thin-film transistor layer TFTL may include a lower metal layer BML, a second buffer film BF2, the first thin-film transistor ST1, a first gate insulating film GI1, a first interlayer insulating film 141, a first capacitor electrode CAE1, a second interlayer insulating film 142, a first anode connection electrode ANDE1, a first organic film 160, a second anode connection electrode ANDE2, and a second organic film 180.

The lower metal layer BML may be disposed on the second substrate SUB2. The lower metal layer BML may overlap a first active layer ACT1 of the first thin-film transistor ST1 in the third direction DR3 in order to prevent a leakage current from being generated in case that light is incident on the first active layer ACT1 of the first thin-film transistor ST1. The lower metal layer BML may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof. In another example, the lower metal layer BML may be omitted.

The second buffer film BF2 may be disposed on the lower metal layer BML. The second buffer film BF2 may be a film for protecting the first thin-film transistor ST1 and the light-emitting layer 172 from moisture permeating through the first substrate SUB1 and the second substrate SUB2 which are susceptible to moisture permeation. The second buffer film BF2 may be formed of inorganic films that are alternately stacked. For example, the second buffer film BF2 may be formed of multiple films in which one or more inorganic films of a silicon nitride layer, a silicon oxynitride layer, a silicon oxide layer, a titanium oxide layer and an aluminum oxide layer are alternately stacked.

The first active layer ACT1 of the first thin-film transistor ST1 may be disposed on the second buffer film BF2. The first active layer ACT1 of the first thin-film transistor ST1 includes polycrystalline silicon, monocrystalline silicon, low-temperature polycrystalline silicon, amorphous silicon, or an oxide semiconductor. The first active layer ACT1 of the first thin-film transistor ST1, which is exposed without being covered by a first gate insulating film GI1, is doped with impurities or ions, and thus may have conductivity. Accordingly, a first source electrode TS1 and a first drain electrode TDI of the first active layer ACT1 of the first thin-film transistor ST1 may be formed.

A first gate insulating film GI1 may be disposed on the first active layer ACT1 of the first thin-film transistor ST1. Although FIG. 5 illustrates that the first gate insulating film GI1 is disposed between the first active layer ACT1 and a first gate electrode TG1 of the first thin-film transistor ST1, but embodiments are not limited thereto. The first gate insulating film GI1 may be disposed between a first interlayer insulating film 141 and the first active layer ACT1 and between the first interlayer insulating film 141 and the second buffer film BF2. The first gate insulating film GI1 may be formed of an inorganic film, for example, a silicon nitride layer, a silicon oxynitride layer, a silicon oxide layer, a titanium oxide layer, or an aluminum oxide layer.

The first gate electrode TG1 of the first thin-film transistor ST1 may be disposed on the first gate insulating film GI1. The first gate electrode TG1 of the first thin-film transistor ST1 may overlap the first active layer ACT1 in the third direction DR3. The first gate electrode TG1 of the first thin-film transistor ST1 may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

The first interlayer insulating film 141 may be disposed on the first gate electrode TG1 of the first thin-film transistor ST1. The first interlayer insulating film 141 may be formed of an inorganic film, for example, a silicon nitride layer, a silicon oxynitride layer, a silicon oxide layer, a titanium oxide layer, or an aluminum oxide layer. The first interlayer insulating film 141 may include inorganic films.

The first capacitor electrode CAE1 may be disposed on the first interlayer insulating film 141. The first capacitor electrode CAE1 may overlap the first gate electrode TG1 of the first thin-film transistor ST1 in the third direction (e.g., Z-axis direction). Since the first interlayer insulating film 141 has a selected dielectric constant, the first capacitor electrode CAE1, the first gate electrode TG1, and the first interlayer insulating film 141 disposed therebetween may form a capacitor. The first capacitor electrode CAE1 may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

The second interlayer insulating film 142 may be disposed on the first capacitor electrode CAE1. The second interlayer insulating film 142 may be formed of an inorganic film, for example, a silicon nitride layer, a silicon oxynitride layer, a silicon oxide layer, a titanium oxide layer, or an aluminum oxide layer. The second interlayer insulating film 142 may include inorganic films.

The first anode connection electrode ANDE1 may be disposed on the second interlayer insulating film 142. The first anode connection electrode ANDE1 may penetrate through the first interlayer insulating film 141 and the second interlayer insulating film 142 to be connected to the first drain electrode TDI of the first thin-film transistor ST1 via a first anode contact hole ANCT1 that exposes the first drain electrode TDI of the first thin-film transistor ST1. The first anode connection electrode ANDE1 may be formed as a single layer or multiple layers made of any one of molybdenum (Mo), aluminum (Al), chromium (Cr), gold (Au), titanium (Ti), nickel (Ni), neodymium (Nd) and copper (Cu), or an alloy thereof.

The first organic film 160 for planarization may be disposed on the first anode connection electrode ANDE1. The first organic film 160 may be formed of an organic film such as acryl resin, epoxy resin, phenolic resin, polyamide resin, polyimide resin and the like.

The second anode connection electrode ANDE2 may be disposed on the first organic film 160. The second anode connection electrode ANDE2 may be connected to the first anode connection electrode ANDE1 through a second anode contact hole ANCT2 which is formed through the first organic film 160 to expose the first anode connection electrode ANDE1. The second anode connection electrode ANDE2 may be formed as a single layer or multiple layers made of any one of molybdenum (Mo), aluminum (Al), chromium (Cr), gold (Au), titanium (Ti), nickel (Ni), neodymium (Nd) and copper (Cu), or an alloy thereof.

A second organic film 180 may be disposed on the second anode connection electrode ANDE2. The second organic film 180 may be formed of an organic film such as acryl resin, epoxy resin, phenolic resin, polyamide resin, polyimide resin and the like.

Although FIG. 5 illustrates that the first thin-film transistor ST1 is configured to be of a top gate type in which the first gate electrode TG1 is positioned on top of the first active layer ACT1, embodiments are not limited thereto. The first thin-film transistor ST1 may be formed as a bottom gate type in which the first gate electrode TG1 is positioned under the first active layer ACT1, or a double gate type in which the first gate electrode TG1 is positioned on and under the first active layer ACT1.

The light-emitting element layer EML may be disposed on the second organic film 180. The light-emitting element layer EML may include light-emitting elements 170 and a bank 190. Each of the light-emitting elements 170 may include a first light-emitting electrode 171, the light-emitting layer 172, and a second light-emitting electrode 173.

The first light-emitting electrode 171 may be formed on the second organic film 180. The first light-emitting electrode 171 may penetrate through the second organic film 180 to be connected to the second anode connection electrode ANDE2 via a third anode contact hole ANCT3 that exposes the second anode connection electrode ANDE2.

In a top emission structure in which light is emitted toward the second light-emitting electrode 173 when viewed with respect to the light-emitting layer 172, the first light-emitting electrode 171 may be formed of a metal material having high reflectivity to have a stacked structure (Ti/Al/Ti) of aluminum and titanium, a stacked structure (ITO/AI/ITO) of aluminum and ITO, an APC alloy, and a stacked structure (ITO/APC/ITO) of an APC alloy and ITO. The APC alloy may be an alloy of silver (Ag), palladium (Pd) and copper (Cu).

The bank 190 may be formed on the second organic film 180 to partition the first light-emitting electrode 171, thereby defining an emission area EA. The bank 190 may include an opening that exposes at least a part of the top surface (or upper surface) of the first light-emitting electrode 171. The bank 190 may be formed to cover the edge portion of the first light-emitting electrode 171. The bank 190 may be formed of an organic film such as acryl resin, epoxy resin, phenolic resin, polyamide resin, polyimide resin and the like.

The emission area EA represents an area in which the first light-emitting electrode 171, the light-emitting layer 172, and the second light-emitting electrode 173 are sequentially stacked, and holes from the first light-emitting electrode 171 and electrons from the second light-emitting electrode 173 are combined with each other in the light-emitting layer 172 to emit light. The emission area EA may be defined by the opening of the bank 190.

The light-emitting layer 172 may be formed on the first light-emitting electrode 171 and the bank 190. The light-emitting layer 172 may be disposed in the opening of the bank 190, but embodiments are not limited thereto. The light-emitting layer 172 may include an organic material to emit light in a selected color. For example, the light-emitting layer 172 may include a hole transporting layer, an organic material layer, and an electron transporting layer.

The second light-emitting electrode 173 may be disposed on the light-emitting layer 172. The second light-emitting electrode 173 may be formed to cover the light-emitting layer 172. The second light-emitting electrode 173 may be a common layer formed in common for all the emission areas EA. In some embodiments, a capping layer may be formed on the second light-emitting electrode 173.

In the top emission structure, the second light-emitting electrode 173 may be formed of transparent conductive oxide (TCO) such as indium tin oxide (ITO) and indium zinc oxide (IZO) capable of transmitting light or a semi-transmissive conductive material such as magnesium (Mg), silver (Ag), or an alloy of magnesium (Mg) and silver (Ag). In case that the second light-emitting electrode 173 is formed of a semi-transmissive conductive material, the light emission efficiency can be increased due to a micro-cavity effect.

The thin-film encapsulation layer TFEL may be disposed on the second light-emitting electrode 173. The thin-film encapsulation layer TFEL may include at least one inorganic film to prevent oxygen or moisture from permeating into the light-emitting element layer. For example, the thin-film encapsulation layer TFEL may include at least one organic film to protect the light-emitting element layer from foreign substances such as dust. For example, the thin-film encapsulation layer TFEL may include a first encapsulation film TFE1, a second encapsulation film TFE2, and a third encapsulation film TFE3.

The first encapsulation film TFE1 (e.g., a first inorganic encapsulation film) may be disposed on the second light-emitting electrode 173. The first encapsulation film TFE1 may be an inorganic film of a single layer or multiple layers. The first encapsulation film TFE1 may be formed as a single film or multiple films in which one or more inorganic films of a silicon nitride layer, a silicon oxynitride layer, a silicon oxide layer, a titanium oxide layer and an aluminum oxide layer are alternately stacked.

The second encapsulation film TFE2 (e.g., a first organic encapsulation film) may be disposed on the first encapsulation film TFE1. The second encapsulation film TFE2 may be an organic film of a single layer or multiple layers. The second encapsulation film TFE2 may include a polymer-based material. Polymer-based materials may include polyethylene terephthalate, polyethylene naphthalate, polycarbonate, polyimide, polyethylene sulfonate, polyoxymethylene, polyarylate, hexamethyldisiloxane, and acrylic resins (e.g., polymethyl methacrylate, polyacrylic acid, or the like), or any combination thereof.

The third encapsulation film TFE3 (e.g., a second inorganic encapsulation film) may be disposed on the second encapsulation film TFE2. The third encapsulation film TFE3 may be an inorganic film of a single layer or multiple layers. The third encapsulation film TFE3 may include the same material as the first encapsulation film TFE1. For example, the third encapsulation film TFE3 may be formed as a single film or multiple films in which one or more inorganic films of a silicon nitride layer, a silicon oxynitride layer, a silicon oxide layer, a titanium oxide layer and an aluminum oxide layer are alternately stacked.

The touch sensor layer TSU may be disposed on the thin-film encapsulation layer TFEL. The touch sensor layer TSU may include touch electrodes for sensing a user's touch in a capacitive manner and the touch lines connecting the touch electrodes to a touch driver. For example, the touch sensor layer TSU may sense the user's touch by using a mutual capacitance method or a self-capacitance method.

In another embodiment, the touch sensor layer TSU may be disposed on a separate substrate disposed on the display layer DU. For example, the substrate supporting the touch sensor layer TSU may be an encapsulation member encapsulating the display layer DU.

The touch electrodes of the touch sensor layer TSU may be disposed in a touch sensor area overlapping the display area. The touch lines of the touch sensor layer TSU may be disposed in the touch peripheral area overlapping the non-display area.

The touch sensor layer TSU may include a first touch insulating film SIL1, a first touch electrode REL, a second touch insulating film SIL2, a second touch electrode TEL, and a third touch insulating film SIL3.

The first touch insulating film SIL1 may be disposed on the thin-film encapsulation layer TFEL. The first touch insulating film SIL1 may have insulating and optical functions. The first touch insulating film SIL1 may include at least one inorganic film. For example, the first touch insulating film SIL1 may be an inorganic film containing at least one of a silicon nitride layer, a silicon oxynitride layer, a silicon oxide layer, a titanium oxide layer, or an aluminum oxide layer. In another example, the first touch insulating film SIL1 may be omitted.

The first touch electrode REL may be disposed on the first touch insulating film SIL1. The first touch electrode REL may not overlap the light-emitting element 170. The first touch electrode REL may be formed as a single layer containing molybdenum (Mo), titanium (Ti), copper (Cu), aluminum (Al), or indium tin oxide (ITO), or may be formed to have a stacked structure (Ti/Al/Ti) of aluminum and titanium, a stacked structure (ITO/Al/ITO) of aluminum and ITO, an Ag—Pd—Cu (APC) alloy, or a stacked structure (ITO/APC/ITO) of APC alloy and ITO.

The second touch insulating film SIL2 may cover the first touch electrode REL and the first touch insulating film SIL1. The second touch insulating film SIL2 may have insulating and optical functions. For example, the second touch insulating film SIL2 may be made of the material in association with the first touch insulating film SIL1.

The second touch electrode TEL may be disposed on the second touch insulating film SIL2. The second touch electrode TEL may not overlap the light-emitting element 170. The second touch electrode TEL may be formed as a single layer containing molybdenum (Mo), titanium (Ti), copper (Cu), aluminum (Al), or indium tin oxide (ITO), or may be formed to have a stacked structure (Ti/Al/Ti) of aluminum and titanium, a stacked structure (ITO/AI/ITO) of aluminum and ITO, an Ag—Pd—Cu (APC) alloy, or a stacked structure (ITO/APC/ITO) of APC alloy and ITO.

The third touch insulating film SIL3 may cover the second touch electrode TEL and the second touch insulating film SIL2. The third touch insulating film SIL3 may have insulating and optical functions. The third touch insulating film SIL3 may be made of the material in association with the second touch insulating film SIL2.

In some embodiments, the first touch insulating film SIL1, the second touch insulating film SIL2, and the third touch insulating film SIL3 may be organic films. Each of the first touch insulating film SIL1, the second touch insulating film SIL2, and the third touch insulating film SIL3 may be an organic film such as acryl resin, epoxy resin, phenolic resin, polyamide resin, polyimide resin, or the like.

The touch sensor layer TSU may further include a planarization layer PAS for planarization. The planarization layer PAS may be formed of an organic film such as acryl resin, epoxy resin, phenolic resin, polyamide resin, polyimide resin and the like.

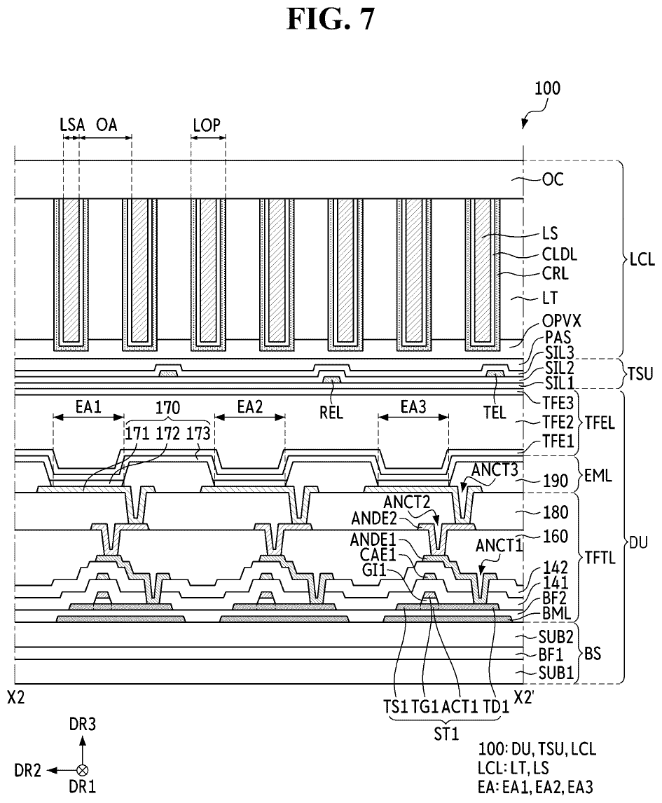

FIG. 6 is a schematic cross-sectional view illustrating a portion of a display device according to an embodiment. FIG. 7 is a schematic cross-sectional view taken along line X2-X2′ of FIG. 6.

Referring to FIGS. 6 and 7 in addition to FIGS. 1 and 2, the display area DA of the display device 10 may include emission areas EA. The emission area EA may be an area where light emitted by the light-emitting element 170 is outputted. The emission area EA may be defined by the bank 190. For example, the emission areas EA may be areas overlapping the light-emitting layer 172 disposed in openings of the bank 190. The emission area EA may be an area in which the first light-emitting electrode 171, the light-emitting layer 172, and the second light-emitting electrode 173 are sequentially stacked while overlapping each other.

In some embodiments, the emission areas EA may include a first emission area EA1, a second emission area EA2, and a third emission area EA3. The drawing illustrates that the display area DA includes three types of emission areas EA, but it may include more or less than three types of emission areas EA, without being limited thereto.

The first emission area EA1 may emit light of a first color, the second emission area EA2 may emit light of a second color, and the third emission area EA3 may emit light of a third color. The light of the first color may be light of a red wavelength band, the light of the second color may be light of a green wavelength band, and the light of the third color may be light of a blue wavelength band. The red wavelength band may be a wavelength band of about 600 nm to about 750 nm, the green wavelength band may be a wavelength band of about 480 nm to about 560 nm, and the blue wavelength band may be a wavelength band of about 370 nm to about 460 nm, but embodiments are not limited thereto.

Each of the first to third emission areas EA1, EA2, and EA3 may have a rectangular, square, or rhombic shape in plan view. For example, as shown in the drawing, each of the first to third emission areas EA1, EA2, and EA3 may have a rectangular shape with rounded corners, but embodiments are not limited thereto.

In an embodiment, the areas of the first to third emission areas EA1, EA2, and EA3 may be the same. The first to third emission areas EA1, EA2, and EA3 may each extend in the first direction DR1 and may be disposed side by side along the second direction DR2.

In another embodiment, the areas of the first to third emission areas EA1, EA2, and EA3 may be different from each other. The first to third emission areas EA1, EA2, and EA3 may each extend in the second direction DR2 and may be disposed side by side along the first direction DR1.

FIG. 6 illustrates the case in which the transmission area OA and the non-transmission area LSA extend in the first direction DR1, as in the display device 10 according to the embodiment of FIG. 1.

The emission area EA of the display area DA may overlap the transmission area OA and the non-transmission area LSA in the third direction DR3. For example, the first to third emission areas EA1, EA2, and EA3 may overlap the transmission area OA and the non-transmission area LSA in the third direction DR3.

The transmission area OA may be an area in which the light-blocking film LS of the light control layer LCL is not disposed. The non-transmission area LSA may be an area in which the light-blocking film LS of the light control layer LCL is disposed.

The light control layer LCL may be disposed on the display layer DU or the touch sensor layer TSU. The light control layer LCL may control a viewing angle of light emitted from the light-emitting layer 172. For example, in case that the light emitted from the light-emitting layer 172 travels at a selected angle or less with respect to the third direction DR3, it may be emitted to the outside. On the other hand, in case that the light emitted from the light-emitting layer 172 travels beyond a selected angle with respect to the third direction DR3, it may be absorbed or blocked by the light-blocking film LS and may not be emitted to the outside.

The light control layer LCL may include a light-transmitting lower film OPVX, the light-transmitting film LT, a core layer CRL, a clad layer CLDL, the light-blocking film LS, and an overcoat layer OC.

The light-transmitting lower film OPVX may be disposed on the display layer DU or the touch sensor layer TSU. The light-transmitting lower film OPVX may transmit light emitted from the light-emitting layer 172. The light-transmitting lower film OPVX may include a transparent organic material. For example, the light-transmitting lower film OPVX may include an organic film such as an acrylic resin, epoxy resin, phenolic resin, polyamide resin, and polyimide resin.

The light-transmitting lower film OPVX may be disposed under the light-transmitting film LT to prevent overflow of the material of the light-transmitting film LT during the inkjet printing process for forming the light-transmitting film LT. For example, the material of the light-transmitting film LT is applied in the form of ink on the light-transmitting lower film OPVX, and overflow of the material of the light-transmitting film LT may be prevented due to the contact angle of the ink and the surface tension of the ink on the light-transmitting lower film OPVX.

For example, in case that a part of the light-transmitting film LT is dry etched to form the light-blocking film LS, the light-transmitting lower film OPVX may prevent the layer positioned below the light control layer LCL from being damaged due to over-etching.

The light-transmitting film LT, the core layer CRL, the clad layer CLDL, the light-blocking film LS, and the overcoat layer OC may be disposed on the light-transmitting lower film OPVX.

The light-transmitting film LT may transmit the light emitted from the light-emitting layer 172. The light-transmitting film LT may include a transparent organic material. For example, the light-transmitting film LT may include an organic film such as acryl resin, epoxy resin, phenolic resin, polyamide resin, polyimide resin and the like.

The light-transmitting film LT may be disposed in the transmission area OA. The light-transmitting films LT may be spaced apart from each other. For example, as shown in FIG. 6, the light-transmitting films LT may each extend in the first direction DR1, and may be spaced apart from each other in the second direction DR2, but embodiments are not limited thereto. The light-transmitting films LT may be disposed alternately with the light-blocking films LS in the first direction DR1 or the second direction DR2.

In some embodiments, the light control layer LCL may include openings LOP that penetrate at least a part of the light-transmitting film LT. The core layer CRL, the clad layer CLDL, and the light-blocking film LS may be disposed in the openings LOP. In some embodiments, as shown in FIG. 7, the openings LOP may penetrate the top surface (or upper surface) of the light-transmitting lower film OPVX, so that the bottom surface of the opening LOP may be positioned at a lower height than the top surface (or upper surface) of the light-transmitting lower film OPVX. However, without being limited thereto, the openings LOP may not penetrate the top surface (or upper surface) of the light-transmitting lower film OPVX. The bottom surface of the opening LOP may be at the same position as the top surface (or upper surface) of the light-transmitting lower film OPVX, or at the higher position than the top surface (or upper surface) of the light-transmitting lower film OPVX.

The core layer CRL may be disposed on the light-transmitting film LT. The core layer CRL may be disposed over the transmission area OA and the non-transmission area LSA. The core layer CRL may be disposed in the opening LOP. The core layer CRL may be disposed along the inner sidewall of the opening LOP. For example, the core layer CRL may have a conformal shape with respect to the inner sidewall of the opening LOP. Accordingly, the core layer CRL may cover the inner sidewall of the opening LOP. The core layer CRL may be surrounded by the clad layer CLDL and the light-transmitting film LT.

The core layer CRL may transmit light emitted from the light-emitting layer 172. In some embodiments, the core layer CRL may include a transparent inorganic material. For example, the core layer CRL may include at least one of silicon nitride (SiNₓ), silicon oxide (SiOₓ), or silicon oxynitride (SiOₓN_{y}). In another embodiment, the core layer CRL may include transparent oxide. For example, the core layer CRL may include at least one of indium tin oxide (ITO) or transparent conductive oxide (TCO).

The clad layer CLDL may be disposed on the core layer CRL. The clad layer CLDL may be disposed over the transmission area OA and the non-transmission area LSA. The clad layer CLDL may be disposed in the opening LOP. The clad layer CLDL may be disposed along the inner sidewall of the core layer CRL. For example, the clad layer CLDL may have a conformal shape with respect to the inner sidewall of the core layer CRL. Accordingly, the clad layer CLDL may cover the inner sidewall of the core layer CRL.

The clad layer CLDL may transmit light emitted from the light-emitting layer 172. In some embodiments, the clad layer CLDL may include a transparent inorganic material. For example, the core layer CRL may include at least one of silicon nitride (SiNₓ), silicon oxide (SiOₓ), or silicon oxynitride (SiOₓN_{y}). For example, the core layer CRL may include at least one of indium tin oxide (ITO) or transparent conductive oxide (TCO).

The light-blocking film LS may absorb or block the light emitted from the light-emitting layer 172. The light-blocking film LS may include a light-blocking organic material. For example, the light-blocking film LS may be a photosensitive resin capable of absorbing or blocking light, and may include an organic material containing an organic black pigment such as carbon black.

The light-blocking film LS may be disposed in the non-transmission area LSA. The light-blocking films LS may be spaced apart from each other. For example, as shown in FIG. 6, the light-blocking films LS may each extend in the first direction DR1, and may be spaced apart from each other in the second direction DR2, but embodiments are not limited thereto.

The light-blocking film LS may be disposed on the clad layer CLDL. The light-blocking film LS may be disposed in the opening LOP. The light-blocking film LS may be disposed in a groove formed by the inner sidewall of the clad layer CLDL. The light-blocking film LS may fill (e.g., completely fill) the groove, but embodiments are not limited thereto.

In an embodiment, the top surface (or upper surface) of the light-blocking film LS may be positioned at the same height as the top surface (or upper surface) of the light-transmitting film LT. After the light-blocking film LS is filled in the opening LOP (or in the groove formed by the inner sidewall of the clad layer CLDL), a portion that overflows the opening LOP may be removed by a chemical mechanical polishing (CMP) process.

The overcoat layer OC may be disposed on the light-transmitting film LT, the core layer CRL, the clad layer CLDL, and the light-blocking film LS. The overcoat layer OC may include an organic film such as acryl resin, epoxy resin, phenolic resin, polyamide resin, polyimide resin and the like.

In some embodiments, the light-transmitting film LT may be formed by an inkjet printing process. The light-transmitting lower film OPVX may be formed by a deposition process. The light-transmitting film LT may include a different material from the light-transmitting lower film OPVX. For example, the light-transmitting film LT may include an ester-based compound and a phosphine oxide compound. For example, the number of carbon atoms of the ester-based compound may be 30 or less. The light-transmitting lower film OPVX may include propylene glycol methyl ether acetate, a methacrylic acid-benzyl methacrylic acid copolymer, a multi-functional acrylate, and a photoinitiator.

In some embodiments, the overcoat layer OC may be formed by a deposition process similarly to the light-transmitting lower film OPVX. Similarly to the light-transmitting lower film OPVX, the overcoat layer OC may include propylene glycol methyl ether acetate, a methacrylic acid-benzyl methacrylic acid copolymer, a multi-functional acrylate, and a photoinitiator.

The refractive index of the core layer CRL may be greater than the refractive index of the light-transmitting lower film OPVX, the refractive index of the light-transmitting film LT, and the refractive index of the clad layer CLDL. For example, the difference between the refractive index of the core layer CRL and the refractive index of the light-transmitting film LT, the difference between the refractive index of the core layer CRL and the refractive index of the clad layer CLDL, and the difference between the refractive index of the core layer CRL and the refractive index of the light-transmitting lower film OPVX may be in a range of about 0.05 to about 0.2. In an embodiment, the refractive index of the core layer CRL may be in a range of about about 1.45 to about 1.8, and the refractive index of the light-transmitting lower film OPVX, the refractive index of the light-transmitting film LT, and the refractive index of the clad layer CLDL may be in a range of about 1.4 to about 1.6.

In the disclosure, the refractive index refers to an absolute refractive index measured using sodium D-lines (e.g., yellow light with a wavelength λ of about 589 nm) at room temperature and humidity (e.g., temperature of 20±15° C., humidity of 65±20%). For example, in the specification, the refractive index may be an absolute refractive index measured based on a wavelength of about 589 nm according to Cauchy's model using a refractive index meter (e.g., M-2000 ellipsometer, J.A. Woollam Co., Inc.) under a temperature of about 25° C. and a relative humidity of about 65%.

In some embodiments, in order for the core layer CRL to have a higher refractive index than that of the clad layer CLDL, the core layer CRL may contain silicon nitride (SiNₓ), and the clad layer CLDL may contain silicon oxide (SiOₓ) or silicon oxynitride (SiOₓN_{y}), but embodiments are not limited thereto.

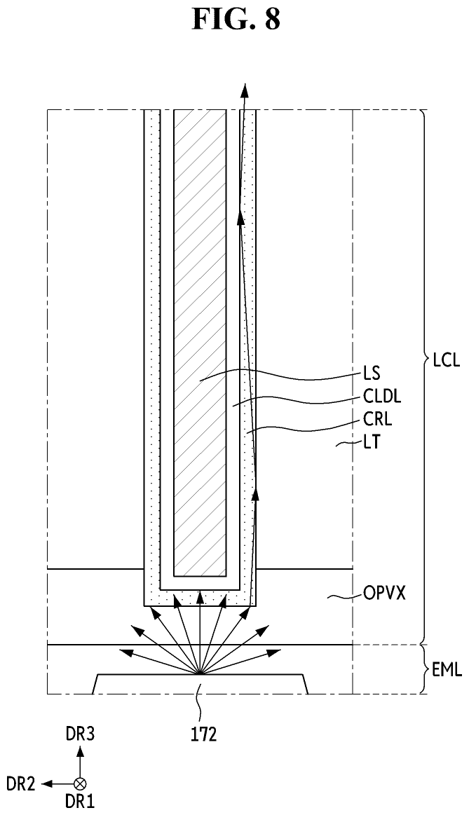

As the light-transmitting lower film OPVX, light-transmitting film LT, and clad layer CLDL with a low refractive index surround the core layer CRL with a high refractive index, the core layer CRL, the light-transmitting lower film OPVX, the light-transmitting film LT, and the clad layer CLDL may perform the same function as an optical fiber. This will be described later with reference to FIG. 8.

In some embodiments, the clad layer CLDL may be omitted, and the light-blocking film LS may contact (e.g., directly contact) the core layer CRL. For example, the light-blocking film LS may play the same role as the clad layer CLDL. For example, in case that the clad layer CLDL is omitted, the refractive index of the light-blocking film LS may be in a range of about 1.4 to about 1.6, similarly to the refractive index of the clad layer CLDL.

FIG. 8 is a schematic diagram showing a path of light traveling along a core layer according to an embodiment.

Referring to FIG. 8 in addition to FIGS. 6 and 7, the light-transmitting lower film OPVX, the light-transmitting film LT, and the clad layer CLDL with a low refractive index may surround the core layer CRL with a high refractive index. Accordingly, the core layer CRL may function as the core of an optical fiber, and the light-transmitting lower film OPVX, the light-transmitting film LT, and the clad layer CLDL may function as the clad of an optical fiber.

For example, as shown in FIG. 8, some of light emitted from the light-emitting layer 172 may be incident on the core layer CRL that is a high refractive film from the light-transmitting lower film OPVX or the light-transmitting film LT that is a low refractive film. For example, according to Snell's law, the exit angle may be smaller than the incident angle based on the normal line extending in the third direction DR3 from the interface between the light-transmitting lower film OPVX and the core layer CRL. For example, light incident on the interface at a larger angle with respect to the third direction DR3 (e.g., lying nearly in the second direction DR2) may be emitted from the interface at a smaller angle with respect to the third direction DR3 (e.g., standing nearly in the third direction DR3). Thereafter, the light may travel in the core layer CRL by total reflection and then be emitted through the top surface (or upper surface) of the core layer CRL.

In the display device 10 according to an embodiment, the light-transmitting lower film OPVX, the light-transmitting film LT, and the clad layer CLDL with a low refractive index may surround the core layer CRL with a high refractive index, so that some lights that have been blocked by the light-blocking film LS may be emitted along the core layer CRL, thereby increasing the light efficiency of the display device 10.

Hereinafter, other embodiments of the display device according to an embodiment will be described. In the following embodiments, description of the same components as those of the above-described embodiment, which are denoted by like reference numerals, will be omitted or simplified, and differences will be mainly described.

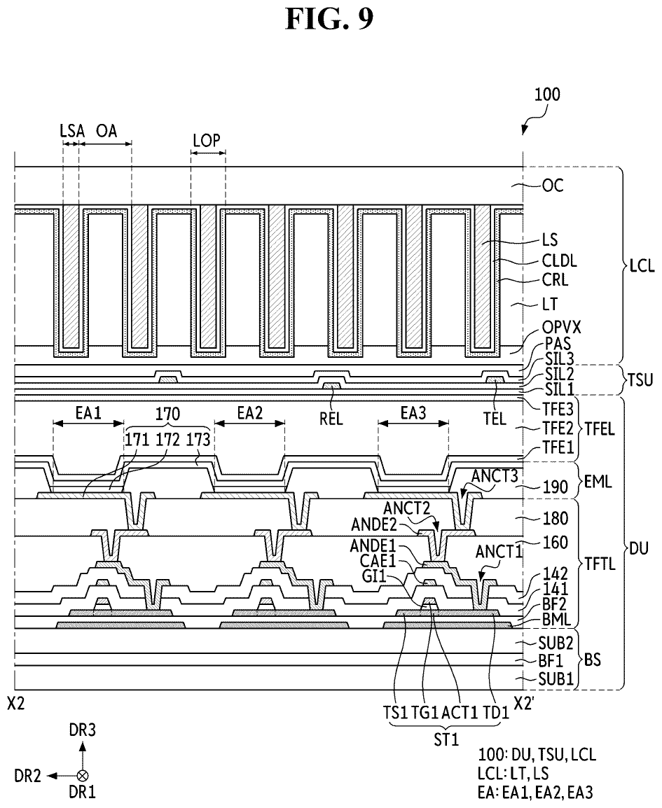

FIG. 9 is a schematic cross-sectional view showing a display panel according to another embodiment.

Referring to FIG. 9 in addition to FIG. 7, the display device 10 according to the embodiment is different from the display device 10 according to the embodiment described with reference to FIG. 7 in that the core layer CRL and the clad layer CLDL are also disposed on the light-transmitting film LT.

For example, the core layer CRL may be disposed in the opening LOP and on the top surface (or upper surface) of the light-transmitting film LT. For example, the core layer CRL may have a conformal shape with respect to the inner sidewall of the opening LOP and the top surface (or upper surface) of the light-transmitting film LT. Accordingly, the core layer CRL may cover the inner sidewall of the light-transmitting film LT and the top surface (or upper surface) of the light-transmitting film LT.

The clad layer CLDL may be disposed in the opening LOP and on the top surface (or upper surface) of the core layer CRL. For example, the clad layer CLDL may have a conformal shape with respect to the inner sidewall of the core layer CRL and the top surface (or upper surface) of the core layer CRL. Accordingly, the clad layer CLDL may cover the inner sidewall of the core layer CRL and the top surface (or upper surface) of the core layer CRL.

In an embodiment, the top surface (or upper surface) of the light-blocking film LS may be positioned at the same height as the top surface (or upper surface) of the clad layer CLDL. In another embodiment, in case that the clad layer CLDL is omitted, the top surface (or upper surface) of the light-blocking film LS may be positioned at the same height as the top surface (or upper surface) of the core layer CRL.

The overcoat layer OC may be disposed on the core layer CRL, the clad layer CLDL, and the light-blocking film LS. The overcoat layer OC may contact (e.g., directly contact) the clad layer CLDL and the light-blocking film LS. In another embodiment, in case that the clad layer CLDL is omitted, the overcoat layer OC may contact (e.g., directly contact) the core layer CRL and the light-blocking film LS.

In the process of manufacturing the display device 10 according to the embodiment described with reference to FIG. 7 and the like and the display device 10 according to an embodiment described with reference to FIG. 9, the light-transmitting film LT may be formed, the opening LOP may be formed, and the core layer CRL and the clad layer CLDL may be sequentially stacked on the opening LOP. For example, a separate process (e.g., dry etching) of removing the core layer CRL and the clad layer CLDL disposed on the top surface (or upper surface) of the light-transmitting film LT may be performed in the case of the display device 10 according to the embodiment described with reference to FIG. 7. However, the process of removing the core layer CRL and the clad layer CLDL may be omitted in the case of the display device 10 according to an embodiment described with reference to FIG. 9, thereby improving the process efficiency.

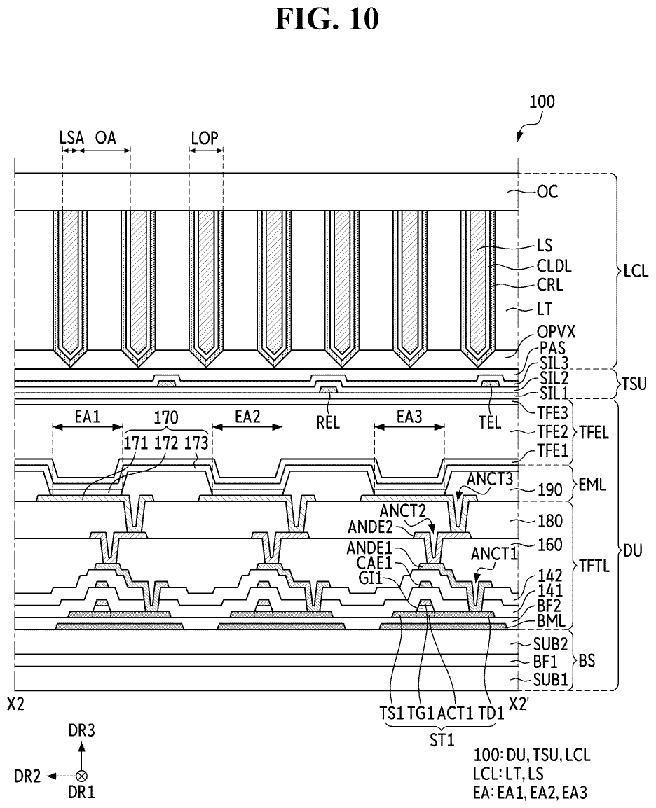

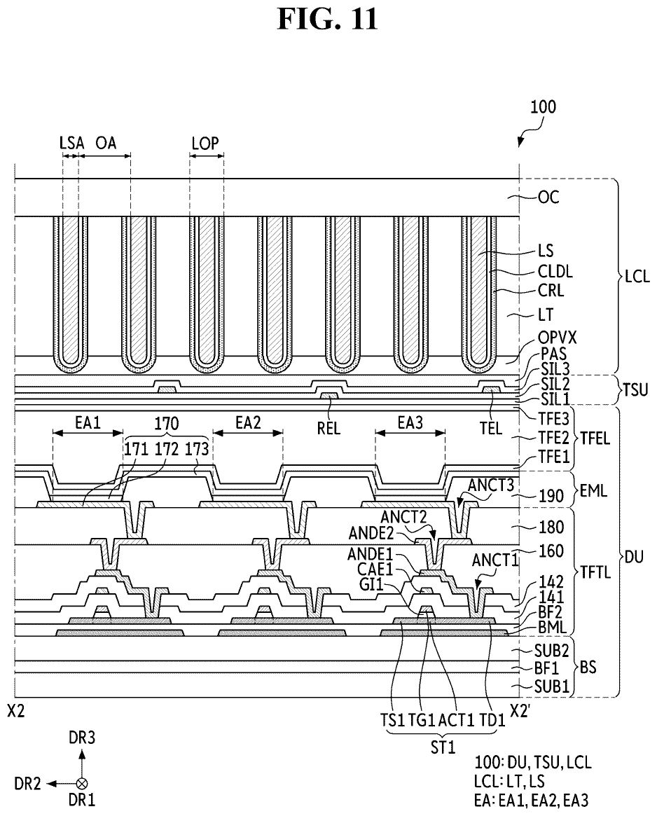

FIGS. 10 and 11 are schematic cross-sectional views of a display panel according to still another embodiment.

Referring to FIGS. 10 and 11, the display device 10 according to an embodiment is different from the display device 10 according to the embodiment described with reference to FIG. 7 and the like in that the bottom shape of the opening LOP is different.

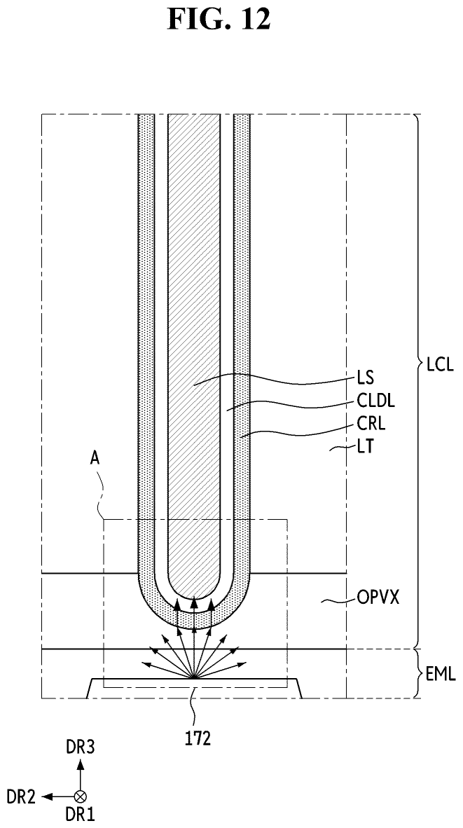

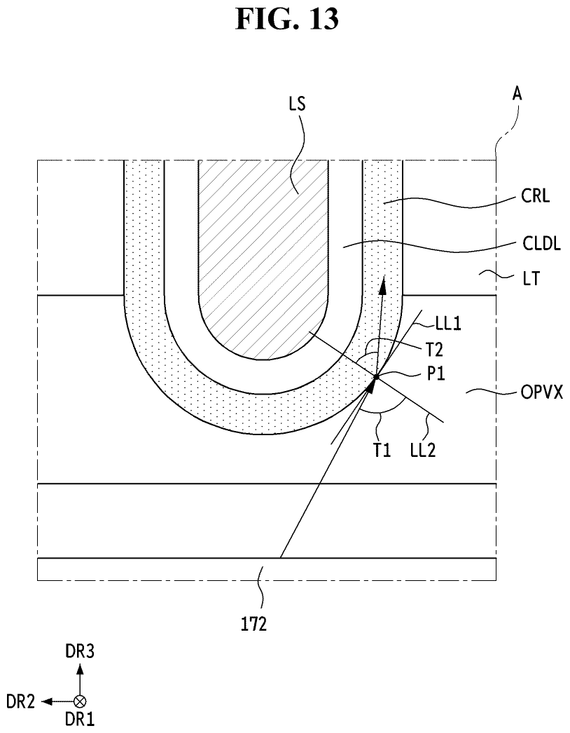

For example, in the display device 10 according to an embodiment, the bottom shape of the opening LOP may be convex toward the light-emitting layer 172. Accordingly, light emitted from the light-emitting layer 172 may be focused at the interface between the core layer CRL and the light-transmitting lower film OPVX (or the light-transmitting film LT). Due to the light-focusing effect, a larger amount of light may travel into the core layer CRL. This will be described later with reference to FIGS. 12 and 13.

In an embodiment, as shown in FIG. 10, the bottom portion of the opening LOP may include flat inclined surfaces. The inclined surfaces may extend in different directions (e.g., 2 o'clock and 10 o'clock in the drawing). A tip may be positioned at a point where the inclined surfaces meet. In the drawing, the inclined surfaces are shown with equal lengths such that the tip is positioned substantially at the center portion of the opening LOP, but embodiments are not limited thereto. For example, the lengths of the inclined surfaces may be different from each other, and the tip may be placed at a position other than the center of the opening LOP.

In another embodiment, as shown in FIG. 11, the bottom portion of the opening LOP may include a curved surface. The curved surface may be a curved surface that smoothly connects both side surfaces of the opening LOP in the second direction DR2. For example, the curved surface may be a part of a circle or an ellipse, but embodiments are not limited thereto.

The bottom shapes of the core layer CRL, the clad layer CLDL, and the light-blocking film LS may each correspond to the bottom shape of the opening LOP. Although the drawing illustrates that the bottom shapes of the core layer CRL, the clad layer CLDL, and the light-blocking film LS are all the same as the bottom shape of the opening LOP, embodiments are not limited thereto. For example, only the bottom shape of the core layer CRL may be the same as the bottom shape of the opening LOP, and the bottom shape of at least one of the clad layer CLDL or the light-blocking film LS may be different from the bottom shape of the opening LOP.

FIG. 12 is a schematic diagram showing a path of light traveling along a core layer according to still another embodiment. FIG. 13 is an enlarged view of area A of FIG. 12.

Referring to FIGS. 12 and 13 in addition to FIGS. 10 and 11, the tangent of the convex bottom surface of the opening LOP at the interface between the light-transmitting lower film OPVX and the core layer CRL may extend in various directions. Accordingly, the incident and exit angles of light may be formed in various ways at the interface between the light-transmitting lower film OPVX and the core layer CRL.

For example, as shown in the drawing, light incident on a first point PI may be incident on the core layer CRL using a first tangent LL1 as an interface. According to Snell's law, an incident angle T1 with respect to a first normal line LL2 may be greater than an exit angle T2 with respect to the first normal line LL2.

In the display device 10 according to the embodiment described with reference to FIG. 7 and the like, the interface between the light-transmitting lower film OPVX and the core layer CRL, which corresponds to the first tangent LL1, extends only in the second direction DR2. On the other hand, in the display device 10 according to an embodiment, the first tangent LL1 may extend in all directions between the second direction DR2 and the third direction DR3, so that the incident and exit angles of light may be formed in various ways. Accordingly, the amount of light incident on the core layer CRL may increase, thereby increasing the light emission efficiency of the display device 10.

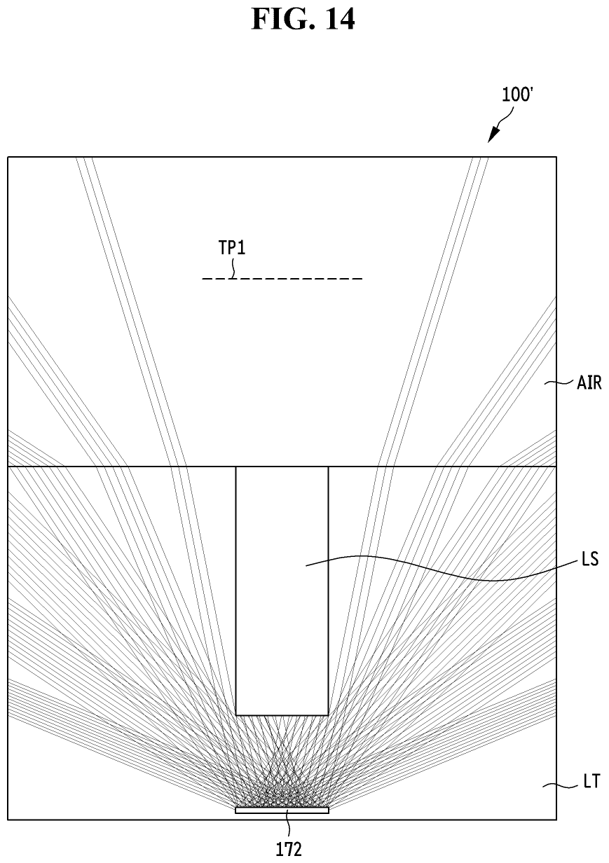

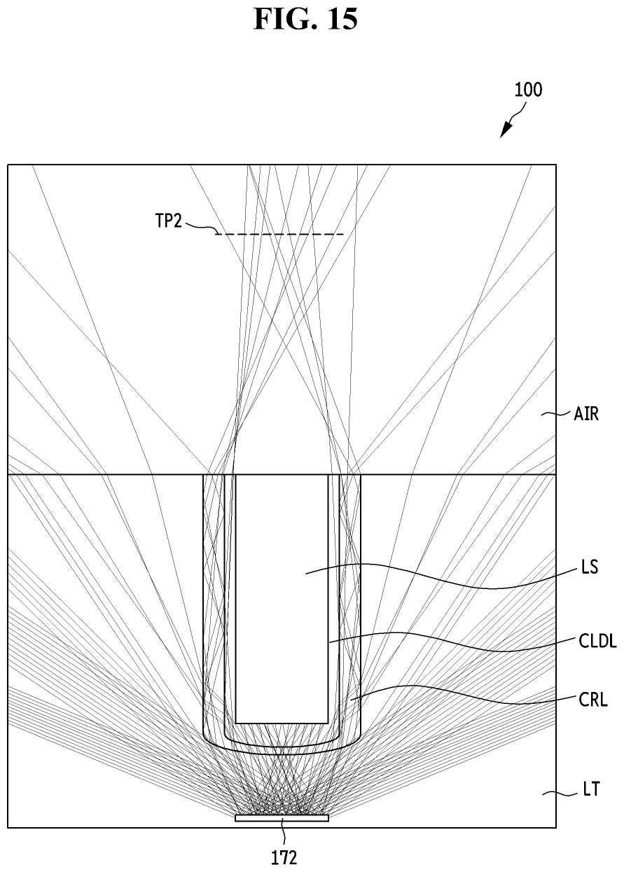

FIG. 14 is a schematic diagram showing a light path in a display panel according to a comparative example. FIG. 15 is a schematic diagram showing a light path in the display panel according to the embodiment of FIG. 11.

Referring to FIGS. 14 and 15, a display panel 100′ according to the comparative example includes only the light-transmitting film LT and the light-blocking film LS, but does not include the core layer CRL and the clad layer CLDL. The display panel 100 according to an embodiment represents the display panel 100 according to the embodiment of FIG. 11.

A first target plane TP1 is provided above the light-blocking film LS of the display panel 100′ according to the comparative example, and a second target plane TP2 is provided above the light-blocking film LS of the display panel 100 according to an embodiment. The first target plane TP1 and the second target plane TP2 are arbitrary planes positioned in the air AIR on the light-blocking film LS.

In the case of the display panel 100′ according to the comparative example, since light emitted from the light-emitting layer 172 is blocked by the light-blocking film LS, no light reaches the first target plane TP1. On the other hand, in the case of the display panel 100 according to an embodiment, light emitted from the light-emitting layer 172 may also be emitted upward above the light-blocking film LS through the core layer CRL. Accordingly, a large amount of light may reach the second target plane TP2.

As such, in accordance with the display panel 100 according to an embodiment, by including the core layer CRL and the clad layer CLDL, the front light emission efficiency on the light-blocking film LS may be increased.

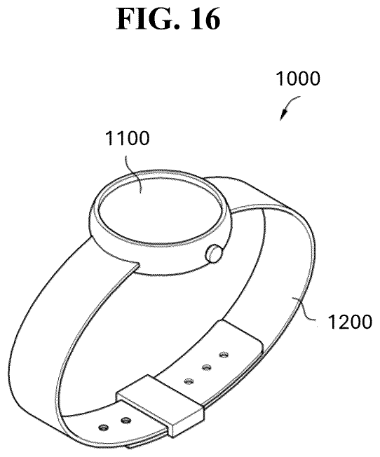

Referring to FIG. 16, the electronic device may be applied to a smart watch 1000 including a display part 1100 and a strap part 1200.

The smart watch 1000 may be a wearable electronic device. For example, the smart watch 1000 may have a structure in which the strap part 1200 is mounted on a wrist of a user. The electronic device may be applied to the display part 1100, so that image data including time information can be provided to the user.

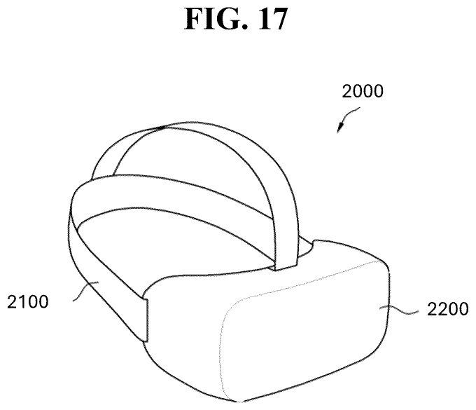

Referring to FIG. 17, the electronic device may be applied to a head mounted display device 2000.

The head mounted display device 2000 may be a wearable electronic device which can be worn on the head of a user. For example, the head mounted display device 2000 may be a wearable device for virtual reality (VR) or mixed reality (MR). The head mounted display device 2000 may include a head mounted band 2100 and a display accommodating case 2200. The head mounted band 2100 may be connected to the display accommodating case 2200. The head mounted band 2100 may include a horizontal band and/or a vertical band, used to fix the head mounted display device 2000 to the head of the user. The horizontal band may be configured to surround a side portion of the head of the user, and the vertical band may be configured to surround an upper portion of the head of the user. However, embodiments are not limited thereto. For example, the head mounted band 2100 may be implemented in the form of a glasses frame, a helmet or the like within the spirit and the scope of the disclosure.

In concluding the detailed description, those skilled in the art will appreciate that many variations and modifications can be made to the preferred embodiments without substantially departing from the principles of the disclosure. Therefore, the disclosed preferred embodiments of the invention are used in a generic and descriptive sense only and not for purposes of limitation.

What is claimed is:

1. A display device comprising:
a substrate;
a light-emitting element layer disposed on the substrate, and comprising a plurality of light-emitting elements; and
a light control layer disposed on the light-emitting element layer, wherein
the light control layer comprises:
a light-transmitting film;
an opening penetrating at least a part of the light-transmitting film;
a core layer disposed in the opening;
a clad layer disposed on the core layer; and
a light-blocking film disposed on the clad layer,
a refractive index of the core layer is greater than a refractive index of the light-transmitting film and a refractive index of the clad layer.

2. The display device of claim 1, wherein the core layer covers an inner sidewall of the opening.

3. The display device of claim 2, wherein the clad layer covers an inner sidewall of the core layer.

4. The display device of claim 3, wherein the light-blocking film is disposed in a groove formed by an inner sidewall of the clad layer.

5. The display device of claim 1, wherein a difference between the refractive index of the core layer and the refractive index of the clad layer is in a range of about 0.05 to about 0.2.

6. The display device of claim 5, wherein the refractive index of the core layer is in a range of about 1.45 to about 1.8.

7. The display device of claim 5, wherein the refractive index of the clad layer is in a range of about 1.4 to about 1.6.

8. The display device of claim 1, wherein
the light control layer further comprises a light-transmitting lower film disposed between the light-emitting element layer and the light-transmitting film, and
the opening penetrates an upper surface of the light-transmitting lower film.

9. The display device of claim 8, wherein a difference between the refractive index of the core layer and a refractive index of the light-transmitting lower film is in a range of about 0.05 to about 0.2.

10. The display device of claim 8, wherein a refractive index of the light-transmitting lower film is in a range of about 1.4 to about 1.6.

11. The display device of claim 1, wherein a bottom portion of the opening has a flat surface.

12. The display device of claim 1, wherein a bottom portion of the opening is convex toward the light-emitting element layer.

13. The display device of claim 12, wherein the bottom portion of the opening has an inclined surface.

14. The display device of claim 12, wherein the bottom portion of the opening has a curved surface.

15. A display device comprising:
a substrate;
a light-emitting element layer disposed on the substrate, and comprising a plurality of light-emitting elements; and
a light control layer disposed on the light-emitting element layer, wherein
the light control layer comprises:
a light-transmitting film;
an opening penetrating at least a part of the light-transmitting film;
a core layer disposed on the light-transmitting film; and
a light-blocking film disposed on the core layer,
a refractive index of the core layer is greater than a refractive index of the light-transmitting film and a refractive index of the light-blocking film.

16. The display device of claim 15, wherein the core layer is disposed on an inner sidewall of the opening and an upper surface of the light-transmitting film.

17. The display device of claim 16, wherein the core layer has a conformal shape along the inner sidewall of the opening and the upper surface of the light-transmitting film.

18. The display device of claim 15, wherein a difference between the refractive index of the core layer and the refractive index of the light-blocking film is in a range of about 0.05 to about 0.2.

19. The display device of claim 15, wherein
the light control layer further comprises a light-transmitting lower film disposed between the light-emitting element layer and the light-transmitting film, and
the opening penetrates an upper surface of the light-transmitting lower film.

20. An electronic device comprising:
a display device, the display device comprising:
a substrate;
a light-emitting element layer disposed on the substrate, and comprising a plurality of light-emitting elements; and
a light control layer disposed on the light-emitting element layer, wherein the light control layer comprises:
a light-transmitting film;
an opening penetrating at least a part of the light-transmitting film;
a core layer disposed in the opening;
a clad layer disposed on the core layer; and
a light-blocking film disposed on the clad layer,
a refractive index of the core layer is greater than a refractive index of the light-transmitting film and a refractive index of the clad layer.
